(19) United States
(12) Patent Application Publication
(10) Pub. No.: US 2021/0175219 A1
(43) Pub. Date: Jun. 10, 2021

(54) DISPLAY AREA HAVING TILES WITH IMPROVED EDGE STRENGTH AND METHODS OF MAKING THE SAME

(71) Applicant: Corning Incorporated, Corning, NY (US)

(72) Inventors: Jiangwei Feng, Painted Post, NY (US); Jen-Chieh Lin, Horseheads, NY (US); Lu Zhang, Painted Post, NY (US)

(21) Appl. No.: 16/771,488

(22) PCT Filed: Dec. 10, 2018
(86) PCT No.: PCT/US2018/064706

§ 371 Date: Jun. 10, 2020

Related U.S. Application Data
(60) Provisional application No. 62/597,111, filed on Dec. 11, 2017.

(51) Int. Cl. H01L 25/13; C03C 17/04; C03C 23/00; C03C 17/25; C03C 17/32; H01L 33/00

(52) U.S. Cl. CPC H01L 25/13; C03C 17/04; C03C 23/006; C03C 17/25; C03C 2218/113; H01L 33/005; C03C 2217/211; C03C 2217/216; C03C 2217/213; C03C 17/32

(57) ABSTRACT

A method of making a display area and a glass tile as well as a display area that includes the glass tile. Prior to assembling the glass tile into the array, an edge treatment is performed on the glass tile, the edge treatment increasing an edge strength of the glass tile, as measured by the four point bend test, to at least about 200 MPa. The edge treatment can, for example, include at least one of plasma jet treatment and protective material application.

### FIELD

This application claims the benefit of priority under 35 U.S.C. § 119 of U.S. Provisional Application Ser. No. 62/597111 filed on Dec. 11, 2017, the content of which is relied upon and incorporated herein by reference in its entirety.

The present disclosure relates generally to a display area comprising an array of tiles and more particularly, to a display area comprising an array of tiles having improved edge strength and methods of making the same.

### BACKGROUND

Display technologies are emerging that benefit from tiling substrates, such as glass substrates, into an array or matrix to form a display larger than the individual substrate tiles. Such technologies include MiroLED. MicroLED can exhibit several advantages over alternative technologies, such as higher brightness, lower power consumption, higher contrast, and faster response. However, due to transfer head sizes and other limitations, the substrates to which MicroLEDs transfer is generally much smaller than the desired final display area, hence, the tiling of the substrates into an array or matrix to form a larger display. Under such conditions, the edge strength of the individual substrate tiles and minimizing the visibility of seams between adjacent tiles are important design considerations.

### SUMMARY

Embodiments disclosed herein include a method for making a display area. The method includes assembling a plurality of glass tiles into an array, wherein each of the plurality of glass tiles in the array is adjacent to at least one other of the plurality of glass tiles in the array. Prior to assembling a glass tile into the array, an edge treatment is performed on the glass tile, the edge treatment increasing an edge strength of the glass tile, as measured by the four point bend test, to at least about 200 MPa.

Embodiments disclosed herein also include a method for making a glass tile that includes performing an edge treatment on the glass tile. The edge treatment increases an edge strength of the glass tile, as measured by the four point bend test, to at least about 200 MPa.

Embodiments disclosed herein also include a display area that includes an array of glass tiles, wherein each of glass tiles in the array is adjacent to at least one other of glass tiles in the array. Each of the glass tiles in the array has an edge strength, as measured by the four point bend test, of at least about 200 MPa.

Additional features and advantages of the embodiments disclosed herein will be set forth in the detailed description which follows, and in part will be readily apparent to those skilled in the art from that description or recognized by practicing the disclosed embodiments as described herein, including the detailed description which follows, the claims, as well as the appended drawings.

It is to be understood that both the foregoing general description and the following detailed description present embodiments intended to provide an overview or framework for understanding the nature and character of the claimed embodiments. The accompanying drawings are included to provide further understanding, and are incorporated into and constitute a part of this specification. The drawings illustrate various embodiments of the disclosure, and together with the description serve to explain the principles and operations thereof.

### BRIEF DESCRIPTION OF THE DRAWINGS

FIG. 1 is a schematic view of an example fusion down draw glass making apparatus and process;

FIG. 2 is an perspective view of a glass tile;

FIG. 3 is a perspective view of at least a portion of a beveling process of an edge surface of a glass tile;

FIG. 4 is a perspective view of at least a portion of an edge treatment process with a plasma jet;

FIG. 5 is a schematic front view of a portion of an edge of an exemplary glass tile prior to an edge treatment process with a plasma jet;

FIG. 6 is a schematic front view of a portion of an edge of an exemplary glass tile subsequent to an edge treatment process with a plasma jet;

FIG. 7 is a schematic side view of an edge of an exemplary glass tile having a protective material on an edge surface and portions of first and second major surfaces adjacent to the edge surface; and

FIG. 8 is a perspective view of a glass tile having a protective material on its edge surfaces and portions of first and second major surfaces adjacent to the edge surfaces;

FIG. 9 is a schematic front view of a display area having an array of glass tiles, each glass tile in the array having a protective material on its edge surfaces and portions of first and second major surfaces adjacent to the edge surfaces;

FIG. 10 is an enlarged, schematic front view of a portion of a glass tile including a plurality of pixels; and

FIG. 11 is a cross-sectional view of a pixel in the plurality of pixels shown in FIG. 10 including at least one microLED.

### DETAILED DESCRIPTION

Reference will now be made in detail to the present preferred embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, for example by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

As used herein, the term “plasma” refers to an ionized gas comprising positive ions and free electrons.

As used herein, the term “atmospheric pressure plasma jet” refers to a flow of plasma discharged from an aperture, wherein the plasma pressure approximately matches that of the surrounding atmosphere, including conditions wherein the plasma pressure is between 90% and 110% of 101.325 kilopascals (standard atmospheric pressure).

As used herein, the term “particles” refers to any type of particles that can be present on a surface, such as glass particles and dust particles.

As used herein, the term, “edge strength, as measured by the four point bend test”, refers to edge strength at which 10% of samples would be expected to fail using the glass flexure fixture four point test set forth in JIS R1601.

As used here, the term “adjacent” refers to immediate proximity with or without physical contact.

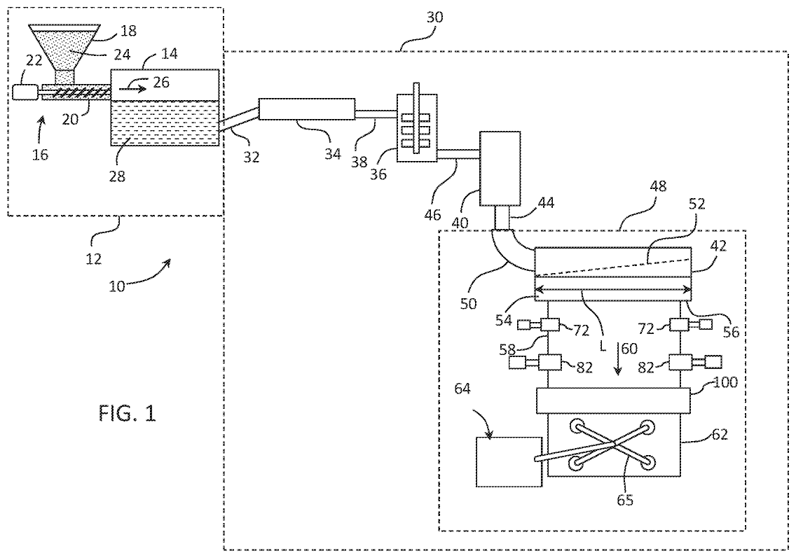

Shown in FIG. 1 is an exemplary glass manufacturing apparatus 10. In some examples, the glass manufacturing apparatus 10 can comprise a glass melting furnace 12 that can include a melting vessel 14. In addition to melting vessel 14, glass melting furnace 12 can optionally include one or more additional components such as heating elements (e.g., combustion burners or electrodes) that heat raw materials and convert the raw materials into molten glass. In further examples, glass melting furnace 12 may include thermal management devices (e.g., insulation components) that reduce heat lost from a vicinity of the melting vessel. In still further examples, glass melting furnace 12 may include electronic devices and/or electromechanical devices that facilitate melting of the raw materials into a glass melt. Still further, glass melting furnace 12 may include support structures (e.g., support chassis, support member, etc.) or other components.

Glass melting vessel 14 is typically comprised of refractory material, such as a refractory ceramic material, for example a refractory ceramic material comprising alumina or zirconia. In some examples glass melting vessel 14 may be constructed from refractory ceramic bricks. Specific embodiments of glass melting vessel 14 will be described in more detail below.

In some examples, the glass melting furnace may be incorporated as a component of a glass manufacturing apparatus to fabricate a glass substrate, for example a glass ribbon of a continuous length. In some examples, the glass melting furnace of the disclosure may be incorporated as a component of a glass manufacturing apparatus comprising a slot draw apparatus, a float bath apparatus, a down-draw apparatus such as a fusion process, an up-draw apparatus, a press-rolling apparatus, a tube drawing apparatus or any other glass manufacturing apparatus that would benefit from the aspects disclosed herein. By way of example, FIG. 1 schematically illustrates glass melting furnace 12 as a component of a fusion down-draw glass manufacturing apparatus 10 for fusion drawing a glass ribbon for subsequent processing into individual glass sheets.

The glass manufacturing apparatus 10 (e.g., fusion down-draw apparatus 10) can optionally include an upstream glass manufacturing apparatus 16 that is positioned upstream relative to glass melting vessel 14. In some examples, a portion of, or the entire upstream glass manufacturing apparatus 16, may be incorporated as part of the glass melting furnace 12.

As shown in the illustrated example, the upstream glass manufacturing apparatus 16 can include a storage bin 18, a raw material delivery device 20 and a motor 22 connected to the raw material delivery device. Storage bin 18 may be configured to store a quantity of raw materials 24 that can be fed into melting vessel 14 of glass melting furnace 12, as indicated by arrow 26. Raw materials 24 typically comprise one or more glass forming metal oxides and one or more modifying agents. In some examples, raw material delivery device 20 can be powered by motor 22 such that raw material delivery device 20 delivers a predetermined amount of raw materials 24 from the storage bin 18 to melting vessel 14. In further examples, motor 22 can power raw material delivery device 20 to introduce raw materials 24 at a controlled rate based on a level of molten glass sensed downstream from melting vessel 14. Raw materials 24 within melting vessel 14 can thereafter be heated to form molten glass 28.

Glass manufacturing apparatus 10 can also optionally include a downstream glass manufacturing apparatus 30 positioned downstream relative to glass melting furnace 12. In some examples, a portion of downstream glass manufacturing apparatus 30 may be incorporated as part of glass melting furnace 12. In some instances, first connecting conduit 32 discussed below, or other portions of the downstream glass manufacturing apparatus 30, may be incorporated as part of glass melting furnace 12. Elements of the downstream glass manufacturing apparatus, including first connecting conduit 32, may be formed from a precious metal. Suitable precious metals include platinum group metals selected from the group of metals consisting of platinum, iridium, rhodium, osmium, ruthenium and palladium, or alloys thereof. For example, downstream components of the glass manufacturing apparatus may be formed from a platinum-rhodium alloy including from about 70 to about 90% by weight platinum and about 10% to about 30% by weight rhodium. However, other suitable metals can include molybdenum, palladium, rhenium, tantalum, titanium, tungsten and alloys thereof.

Downstream glass manufacturing apparatus 30 can include a first conditioning (i.e., processing) vessel, such as fining vessel 34, located downstream from melting vessel 14 and coupled to melting vessel 14 by way of the above-referenced first connecting conduit 32. In some examples, molten glass 28 may be gravity fed from melting vessel 14 to fining vessel 34 by way of first connecting conduit 32. For instance, gravity may cause molten glass 28 to pass through an interior pathway of first connecting conduit 32 from melting vessel 14 to fining vessel 34. It should be understood, however, that other conditioning vessels may be positioned downstream of melting vessel 14, for example between melting vessel 14 and fining vessel 34. In some embodiments, a conditioning vessel may be employed between the melting vessel and the fining vessel wherein molten glass from a primary melting vessel is further heated to continue the melting process, or cooled to a temperature lower than the temperature of the molten glass in the melting vessel before entering the fining vessel.

Bubbles may be removed from molten glass 28 within fining vessel 34 by various techniques. For example, raw materials 24 may include multivalent compounds (i.e. fining agents) such as tin oxide that, when heated, undergo a chemical reduction reaction and release oxygen. Other suitable fining agents include without limitation arsenic, antimony, iron and cerium. Fining vessel 34 is heated to a temperature greater than the melting vessel temperature, thereby heating the molten glass and the fining agent. Oxygen bubbles produced by the temperature-induced chemical reduction of the fining agent(s) rise through the molten glass within the fining vessel, wherein gases in the molten glass produced in the melting furnace can diffuse or coalesce into the oxygen bubbles produced by the fining agent. The enlarged gas bubbles can then rise to a free surface of the molten glass in the fining vessel and thereafter be vented out of the fining vessel. The oxygen bubbles can further induce mechanical mixing of the molten glass in the fining vessel.

Downstream glass manufacturing apparatus 30 can further include another conditioning vessel such as a mixing vessel 36 for mixing the molten glass. Mixing vessel 36 may be located downstream from the fining vessel 34. Mixing vessel 36 can be used to provide a homogenous glass melt composition, thereby reducing cords of chemical or thermal inhomogeneity that may otherwise exist within the fined molten glass exiting the fining vessel. As shown, fining vessel 34 may be coupled to mixing vessel 36 by way of a second connecting conduit 38. In some examples, molten glass 28 may be gravity fed from the fining vessel 34 to mixing vessel 36 by way of second connecting conduit 38. For instance, gravity may cause molten glass 28 to pass through an interior pathway of second connecting conduit 38 from fining vessel 34 to mixing vessel 36. It should be noted that while mixing vessel 36 is shown downstream of fining vessel 34, mixing vessel 36 may be positioned upstream from fining vessel 34. In some embodiments, downstream glass manufacturing apparatus 30 may include multiple mixing vessels, for example a mixing vessel upstream from fining vessel 34 and a mixing vessel downstream from fining vessel 34. These multiple mixing vessels may be of the same design, or they may be of different designs.

Downstream glass manufacturing apparatus 30 can further include another conditioning vessel such as delivery vessel 40 that may be located downstream from mixing vessel 36. Delivery vessel 40 may condition molten glass 28 to be fed into a downstream forming device. For instance, delivery vessel 40 can act as an accumulator and/or flow controller to adjust and/or provide a consistent flow of molten glass 28 to forming body 42 by way of exit conduit 44. As shown, mixing vessel 36 may be coupled to delivery vessel 40 by way of third connecting conduit 46. In some examples, molten glass 28 may be gravity fed from mixing vessel 36 to delivery vessel 40 by way of third connecting conduit 46. For instance, gravity may drive molten glass 28 through an interior pathway of third connecting conduit 46 from mixing vessel 36 to delivery vessel 40.

Downstream glass manufacturing apparatus 30 can further include forming apparatus 48 comprising the above-referenced forming body 42 and inlet conduit 50. Exit conduit 44 can be positioned to deliver molten glass 28 from delivery vessel 40 to inlet conduit 50 of forming apparatus 48. For example in examples, exit conduit 44 may be nested within and spaced apart from an inner surface of inlet conduit 50, thereby providing a free surface of molten glass positioned between the outer surface of exit conduit 44 and the inner surface of inlet conduit 50. Forming body 42 in a fusion down draw glass making apparatus can comprise a trough 52 positioned in an upper surface of the forming body and converging forming surfaces 54 that converge in a draw direction along a bottom edge 56 of the forming body. Molten glass delivered to the forming body trough via delivery vessel 40, exit conduit 44 and inlet conduit 50 overflows side walls of the trough and descends along the converging forming surfaces 54 as separate flows of molten glass. The separate flows of molten glass join below and along bottom edge 56 to produce a single ribbon of glass 58 that is drawn in a draw or flow direction 60 from bottom edge 56 by applying tension to the glass ribbon, such as by gravity, edge rolls 72 and pulling rolls 82, to control the dimensions of the glass ribbon as the glass cools and a viscosity of the glass increases. Accordingly, glass ribbon 58 goes through a visco-elastic transition and acquires mechanical properties that give the glass ribbon 58 stable dimensional characteristics. Glass ribbon 58 may, in some embodiments, be separated into individual glass sheets 62 by a glass separation apparatus 100 in an elastic region of the glass ribbon. A robot 64 may then transfer the individual glass sheets 62 to a conveyor system using gripping tool 65, whereupon the individual glass sheets may be further processed.

Glass sheets 62 may further be separated into individual glass tiles by one or more methods known to persons of ordinary skill in the art such as, for example, a mechanical cutting technique. Exemplary cutting techniques include, for example, use of a semiconductor dicing saw or a mechanical scribe. Glass sheets 63 may also be separated into individual glass tiles by other techniques, such as, for example, laser-based cutting and separation techniques.

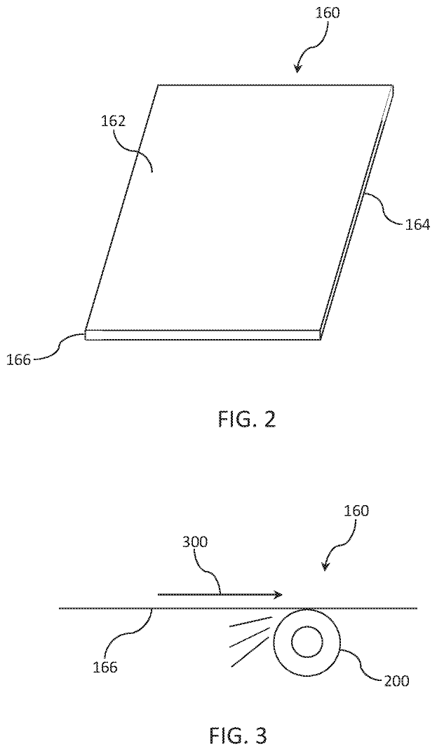

FIG. 2 shows a perspective view of a glass tile 160 having a first major surface 162, a second major surface 164 extending in a generally parallel direction to the first major surface (on the opposite side of the glass tile 160 as the first major surface) and an edge surface 166 extending between the first major surface and the second major surface and extending in a generally perpendicular direction to the first and second major surfaces 162, 164.

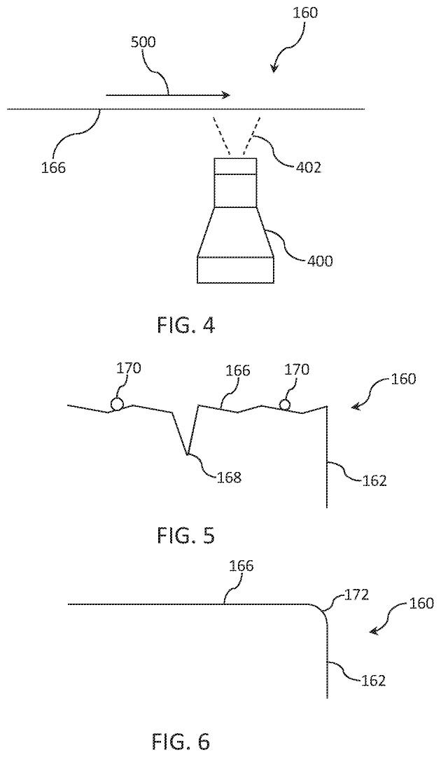

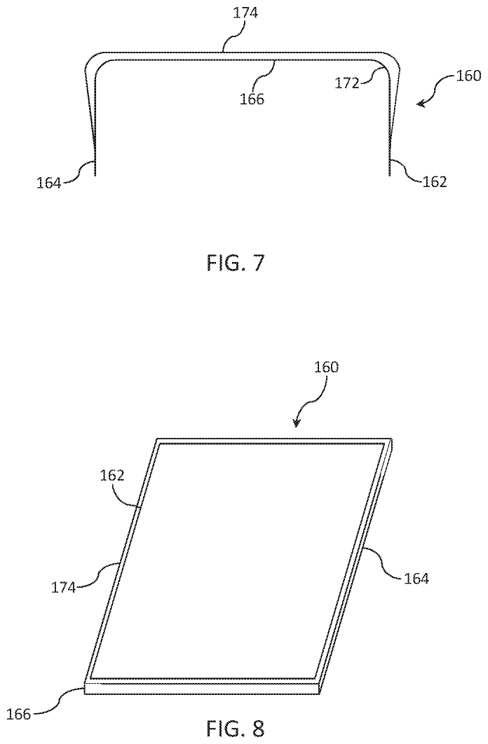

FIG. 3 shows a perspective view of at least a portion of a beveling process of an edge surface 166 of a glass tile 160. As shown in FIG. 3, beveling process includes applying a grinding wheel 200 to edge surface 166, wherein the grinding wheel 200 moves relative to edge surface 166 in the direction indicated by arrow 300. Beveling process may further include applying at least one polishing wheel (not shown) to edge surface 166. Such beveling process can lead to the presence of numerous glass particles, as well as surface and sub-surface damage (i.e., irregular topography), on edge surface 166.

Downstream processing of glass tile 160 may involve application of mechanical or chemical treatments on edge surfaces 166, which can result in additional particle generation due to the presence of irregular edge surface topography. Such particles may migrate to at least one surface of glass tile 160. Accordingly, embodiments disclosed herein include those in which irregular edge surface topography is removed, while at the same time removing and/or reducing edge particles present on the edge surfaces 166 as well as removing reaction by-products that may be formed upon removal of the irregular edge surface topography.

FIG. 4 shows a perspective view of at least a portion of a treatment process of an edge surface 166 of a glass tile 160 with a plasma jet 402. As shown in FIG. 4, treatment process includes directing a flow of plasma, via plasma jet 402, toward edge surface 166, wherein plasma jet head 400 moves relative to edge surface 166 in the direction indicated by arrow 500. In certain exemplary embodiments, plasma jet 402 comprises an atmospheric pressure plasma jet.

Plasma jet 402 can be directed toward edge surface 166 under a variety of processing parameters. In certain exemplary embodiments, plasma jet 402 can be generated at a power of at least about 300 watts, such as a power of at least about 500 watts, including a power of from about 300 watts to about 800 watts and further including a power of from about 500 watts to about 800 watts.

In certain exemplary embodiments, plasma jet 402 is generated via a direct current high voltage discharge that generates a pulsed electric arc, such as a voltage discharge of at least about 5 kV, such as from about 5 kV to about 15 kV. In certain exemplary embodiments, plasma jet 402 is generated at a frequency of at least about 10 kHz, such as from about 10 kHz to about 100 kHz. In certain exemplary embodiments, plasma jet can have a beam length of from about 5 millimeters to about 40 millimeters and a widest beam width of from about 3 millimeters to about 15 millimeters.

In certain exemplary embodiments, the distance between the portion of plasma jet head 400 that is closest to edge surface 166 and edge surface 166 (referred to herein as “gap distance”), is at least about 2 millimeters, such as at least about 3 millimeters, and further such as at least about 4 millimeters, and yet further such as at least about 5 millimeters, such as from about 2 millimeters to about 10 millimeters, including from about 5 millimeters to about 10 millimeters.

In certain exemplary embodiments, the speed of relative movement between plasma jet head 400 and edge surface 166 (referred to herein as “scan speed”) can range from about 1 millimeter per second to about 50 millimeters per second, such as from about 5 millimeters per second to about 25 millimeters per second, and further such as from about 10 millimeters per second to about 20 millimeters per second.

In certain exemplary embodiments, the number of times that the plasma jet head 400 moves relative to the entire length of edge surface 166 (referred to herein as “scan pass”) can be at least 1 pass, such as at least 2 passes, and further such as at least 3 passes, and yet further such as at least 4 passes, including from 1 pass to 10 passes, and further including from 2 passes to 6 passes.

In certain exemplary embodiments, the plasma comprises at least one component selected from the group consisting of nitrogen, argon, oxygen, hydrogen, and helium that is excited and at least partially converted to the plasma state. In certain exemplary embodiments, the plasma comprises at least one component selected from the group consisting of nitrogen, argon, and hydrogen, such as at least two components selected from the group consisting of nitrogen, argon, and hydrogen, and further such as embodiments in which the plasma comprises each of nitrogen, argon, and hydrogen. When the plasma comprises at least one of nitrogen, argon, and hydrogen, the nitrogen content can, for example, range from about 50 mol % to about 100 mol %, such as from about 60 mol % to about 90 mol %, the argon content can, for example, range from about 0 mol % to about 20 mol %, such as from about 5 mol % to about 15 mol %, and the hydrogen content can, for example, range from about 0 mol % to about 10 mol %, such as from about 1 mol % to about 5 mol %.

In certain exemplary embodiments, treatment process comprising directing a flow of plasma, via plasma jet 402, toward edge surface 166, can result in a substantial reduction of particle density on edge surface 166, such as a particle density reduction of at least 1 order of magnitude, and further such as a particle density reduction of at least 2 orders of magnitude, and yet further such as a particle density reduction of at least 3 orders of magnitude. For example, directing a flow of plasma toward edge surface 166, according to embodiments disclosed herein, can reduce a density of particles on edge surface 166 to less than about 40 per 0.1 square millimeter, such as less than about 30 per 0.1 square millimeter, and further such as less than about 20 per 0.1 square millimeter, and yet further such as less than about 10 per 0.1 square millimeter, including from about 0 to about 40 particles per 0.1 square millimeter, and further including from about 1 to about 30 particles per 0.1 square millimeter, and yet further from about 2 to about 20 particles per 0.1 square millimeter.

Embodiments disclosed herein include those in which plasma jet 402 is applied toward edge surface 166 after or in lieu of an edge beveling process, such as the exemplary edge beveling process shown in FIG. 3. For example, in certain exemplary embodiments, plasma jet 402 may be applied toward edge surface 166 of glass tile 160 immediately following separation of glass tile 160 from glass sheet 62. Alternatively, subsequent processing steps, such as the exemplary edge beveling process shown in FIG. 3, may be applied to glass tile 160, prior to application of plasma jet 402 toward edge surface 166 of glass tile 160.

FIG. 5 is a schematic front view of a portion of an edge 166 of an exemplary glass tile 160 prior to an edge treatment process with a plasma jet. As shown in FIG. 5, irregular edge surface topography is shown as being magnified or exaggerated and includes crack feature 168 as well as adhered glass particles 170.

FIG. 6 is a schematic front view of a portion of an edge 166 of an exemplary glass tile 160 subsequent to an edge treatment process with a plasma jet. As shown in FIG. 6, irregular edge surface topography, including crack feature 168 as well as adhered glass particles 170, has been smoothed over. In addition, the intersection of edge 166 and first major surface 162 of glass tile 160 comprises a rounded corner 172.

In certain exemplary embodiments, edge surface 166 may be heated, for example, by an electrical resistance heater or an induction heater, to a temperature of at least about 100° C., such as at least about 200° C., and further such as at least about 300° C., and yet further such as at least about 400° C., and still yet further such as at least about 500° C., including a temperature ranging from about 100° C. to about 600° C. prior to directing the flow of plasma toward the edge surface 166. Exemplary embodiments also include those in which temperature of edge surface 166 is maintained in the above-referenced ranges for a period of time subsequent to directing a flow of plasma toward the edge surface 166. Such heat treatment can potentially reduce edge tensile stress.

FIG. 7 is a schematic side view of an edge of an exemplary glass tile 160 having a protective material 174 on an edge surface 166 and portions of first major surface 162 and second major surface 164 adjacent to the edge surface 166. While not limited to any particular amount of coverage, in certain exemplary embodiments protective material 174 may cover at least about 1% of first major surface 162 and second major surface 164, such as from about 1% to about 10% of first major surface 162 and second major surface 164, including from about 2% to about 5% of first major surface 162 and second major surface 164. While FIG. 7 shows protective material 174 on portions of first major surface 162 and second major surface 164, it is to be understood that embodiments disclosed herein include those in which protective material 174 is only on edge surface 166.

As shown in FIG. 7, protective material 174 on portions of first major surface 162 and second major surface 164 decreases in thickness between rounded corner 172 and portion of protective material on first major surface 162 and second major surface 164 that is furthest away from rounded corner 172. While FIG. 7 shows protective material 174 decreasing in thickness on first major surface 162 and second major surface 164, it is to be understood that embodiments disclosed herein include those in which protective material 174 is of relatively constant thickness on first major surface 162 and second major surface 164. The combination of rounded corners 172 and protective material 174 covering not only edge surface 166 but also at least a portion of first major surface 162 and second major surface 164 can enable glass tiles 160 with exceptional edge strength and resistance to cracking or chipping.

As shown in FIG. 7, protective material 174 is of relatively constant thickness on edge surface 166. While not limited to any particular thickness, in certain exemplary embodiments protective material 174 covering edge surface 166 may have a thickness of at least about 1 micron, such as from about 1 micron to about 500 microns. In addition, protective material 174 covering at least a portion of first major surface 162 and second major surface 164 may have a thickness of at least about 1 micron, such as from about 1 micron to about 500 microns, including a thickness that decreases from between about 1 micron and about 500 microns near rounded corner 172 to less than about 0.1 microns on first major surface 162 and second major surface 164 that is furthest away from rounded corner 172.

In certain exemplary embodiments, protective material 174 comprises a solution-based coating. The solution can include organic or inorganic (e.g., water-based) solvents and the solution-based coating can, for example, be selected from not only a solution but also at least one of a sol-gel, a dispersion, a suspension, and a slurry. When the solution-based coating comprises a sol-gel, the sol-gel can be thermally or UV-curable. Exemplary, solution-based coatings include polyimide (PI) and polydimethylsiloxane (PDMS).

The solution-based coating may be applied by any method known to persons having ordinary skill in the art, such as, for example, dipping, spraying, brushing, rolling, and vapor deposition. Following application, and depending on the type of coating applied, a drying technique known to persons of ordinary skill in the art, such as for example, convection drying or microwave drying, may be used. In certain exemplary embodiments, portion of glass tile 160 not intended to be covered by solution-based coating may be covered with a masking material that can be removed following application and curing and/or drying of protective material 174.

In certain exemplary embodiments, protective material 174 comprises at least one inorganic material. Exemplary inorganic materials can include glass frit, such as a relatively transparent glass frit, and metal oxides such as silica (SiO₂), zinc oxide (ZnO), and tin oxide (SnO₂). While such materials may be applied in a solution-based coating, such as described above, they may be also applied according to other methods including, for example, by flame deposition. For example, when silica is applied via flame deposition, a silane precursor in a carrier gas, such as nitrogen, may react with oxygen in a flame to produce silica. And, in certain exemplary embodiments, such as when the protective material 174 comprises glass frit, the protective material may be applied using a pen-dispenser, which may, in certain exemplary embodiments, be followed by a thermal sintering or laser sealing process to fill any cracks and thereby further increase edge strength.

In exemplary embodiments, treatment processes as described herein, including directing a flow of plasma, via plasma jet 402, toward edge surface 166 of a glass tile 160 and/or applying a protective material 174 on an edge surface 166 of the glass tile 160 can result in an edge strength as measured by the four point bend test, of at least about 200 MPa, such as at least about 250 MPa, and further such as at least about 300 MPa. For example, in certain embodiments, the distance of the extension direction of the edge between the first and second major surfaces (i.e., the thickness of glass tile 160) is less than or equal to about 0.5 millimeters and treatment processes as described herein can result in an edge strength, as measured by the four point bend test, of at least about 200 MPa, such as at least about 250 MPa, and further such as at least about 300 MPa.

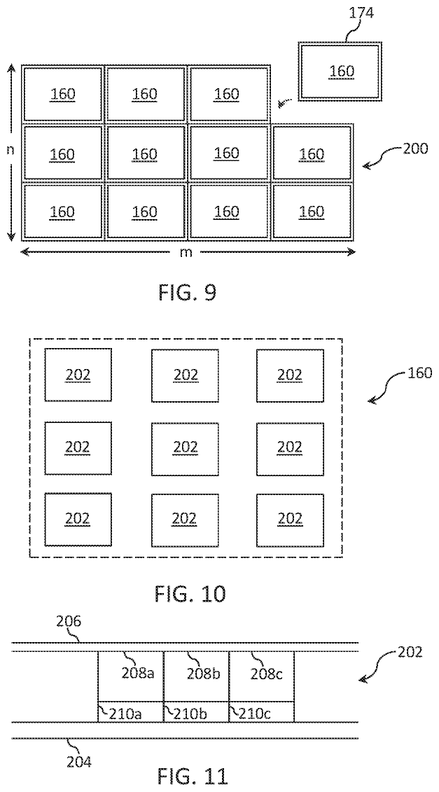

FIG. 8 is a perspective view of a glass tile 160 having a protective material 174 on its edge surfaces 166 and portions of its first major surface 162 and second major surface 164 adjacent to its edge surfaces 166. FIG. 9 is a schematic front view of a display area 200 having an m×n array of glass tiles 160, each glass tile 160 in the array having a protective material 174 on its edge surfaces and portions of first and second major surfaces adjacent to the edge surfaces. As shown in FIG. 9, a glass tile 160 is being added to the array 200. In the array 200 of glass tiles 160 shown in FIG. 9, each of glass tiles 160 in the array 200 is adjacent to at least one other of the plurality of glass tiles 160 in the array 200. While array 200 is shown as having a generally rectangular shape, it is understood that embodiments disclosed herein are not so limited and include a variety of shapes, sizes, and planarity including, but not limited to circular, elliptical, and other geometric and polygonal shapes.

In being adjacent to at least one other of the plurality of glass tiles 160 in the array 200, each glass tile 160 in the array 200 may be in physical contact with at least one other glass tile 160 in the array 200. For example, each glass tile 160 in the array 200 may be in physical contact with each glass tile in its immediate proximity. Each glass tile 160 may also be spaced a predetermined distance from glass tiles 160 in its immediate proximity, such as at least about 1 micron away from the next nearest glass tile 160, including from about 1 micron to about 20 microns, such as from about 2 microns to about 10 microns away from the next nearest glass tile 160.

FIG. 10 shows an enlarged, schematic front view of a portion of a glass tile 160 comprising a plurality of pixels 202. The number of pixels 202 per glass tile 160 can vary depending on the application, which is dependent on pixel pitch (i.e., distance between immediately adjacent pixels) as well as the size of the glass tile 160.

FIG. 11 shows a cross-sectional view of a pixel 202 in the plurality of pixels shown in FIG. 10 including at least one microLED. Specifically, FIG. 11 shows a pixel 202 comprising a substrate 204, a glass or film 206 opposite the substrate 204, and three microLEDs, 208a, 208b, and 208c, each microLED with a corresponding electrode, 210a, 210b, and 210c to control the operation of the respective microLED. For example, in some embodiments, one of the microLEDs can include a red microLED, one of the microLEDs can include a green microLED, and one of the microLEDs can include a blue microLED.

While the above embodiments have been described with reference to a fusion down draw process, it is to be understood that such embodiments are also applicable to other glass forming processes, such as float processes, slot draw processes, up-draw processes, tube drawing processes, and press-rolling processes.

It will be apparent to those skilled in the art that various modifications and variations can be made to embodiment of the present disclosure without departing from the spirit and scope of the disclosure. Thus it is intended that the present disclosure cover such modifications and variations provided they come within the scope of the appended claims and their equivalents.

1. A method for making a display area comprising:
assembling a plurality of glass tiles into an array, wherein each of the plurality of glass tiles in the array is adjacent to at least one other of the plurality of glass tiles in the array; and
wherein, prior to assembling a glass tile into the array, an edge treatment is performed on the glass tile, the edge treatment increasing an edge strength of the glass tile, as measured by the four point bend test, to at least about 200 MPa.

2. The method of claim 1, wherein the edge treatment comprises directing a flow of plasma toward an edge surface of the glass tile.

3. The method of claim 2, wherein the flow of plasma comprises an atmospheric pressure plasma jet.

4. (canceled)

5. The method of claim 2, wherein the edge surface is heated to a temperature of at least about 100° C. prior to directing the flow of plasma toward the edge surface.

6. The method of claim 1, wherein the edge treatment comprises applying a protective material on an edge surface of the glass tile.

7. (canceled)

8. The method of claim 6, wherein the protective material comprises a solution-based coating.

9. (canceled)

10. (canceled)

11. (canceled)

12. (canceled)

13. The method of claim 6, wherein the protective material is applied to the edge surface by flame deposition.

14. A method for making a glass tile comprising performing an edge treatment on the glass tile, the edge treatment increasing an edge strength of the glass tile, as measured by the four point bend test, to at least about 200 MPa.

15. The method of claim 14, wherein the edge treatment comprises directing a flow of plasma toward an edge surface of the glass tile.

16. The method of claim 15, wherein the flow of plasma comprises an atmospheric pressure plasma jet.

17. (canceled)

18. The method of claim 15, wherein the edge surface is heated to a temperature of at least about 100° C. prior to directing the flow of plasma toward the edge surface.

19. The method of claim 14, wherein the edge treatment comprises applying a protective material on an edge surface of the glass tile.

20. (canceled)

21. The method of claim 19, wherein the protective material comprises a solution-based coating.

22. (canceled)

23. (canceled)

24. (canceled)

25. (canceled)

26. The method of claim 19, wherein the protective material is applied to the edge surface by flame deposition.

27. A display area comprising:
an array of glass tiles, wherein each of glass tiles in the array is adjacent to at least one other of glass tiles in the array; and
each of the glass tiles in the array has an edge strength, as measured by the four point bend test, of at least about 200 MPa.

28. The display area of claim 27, wherein each of the glass tiles in the array comprises a protective material on an edge surface of the glass tile.

29. (canceled)

30. The display area of claim 28, wherein the protective material comprises a solution-based coating.

31. (canceled)

32. (canceled)

33. (canceled)

34. (canceled)

35. The display area of claim 28, wherein each of the glass tiles in the array comprises a plurality of microLEDs.
